(19) United States
(12) Patent Application Publication
(10) Pub. No.: US 2015/0101535 A1
(43) Pub. Date: Apr. 16, 2015

(54) VAPOR DEPOSITION APPARATUS

(71) Applicant: Samsung Display Co., Ltd., Yongin-City (KR)

(72) Inventors: Sung-Yong Lee, Yongin-City (KR); Sung-Hun Key, Yongin-City (KR); In-Kyo Kim, Yongin-City (KR); Cheol-Min Jang, Yongin-City (KR); Myung-Soo Huh, Yongin-City (KR)

(73) Assignee: Samsung Display Co., Ltd., Yongin-City (KR)

(21) Appl. No.: 14/188,017

(22) Filed: Feb. 24, 2014

(30) Foreign Application Priority Data
Oct. 10, 2013 (KR) 10-2013-0120873

(51) Int. Cl. C23C 16/455; C23C 16/50; C23C 16/52

(52) U.S. Cl. CPC C23C 16/45563; C23C 16/52; C23C 16/50
USPC 118/712; 118/723 R

(57) ABSTRACT

A vapor deposition apparatus includes a substrate mount unit on which a substrate is mounted, a plurality of first nozzle units which injects a first raw material in a direction of the substrate mount unit, a plurality of second nozzle units which is alternately disposed with the plurality of first nozzle units and injects a second raw material in the direction of the substrate mount unit, and a plasma module unit which supplies the second raw material to the plurality of second nozzle units. The second raw material is a radical, and the substrate mount unit includes an electrostatic generation part.

This application claims priority to Korean Patent Application No. 10-2013-0120873, filed on Oct. 10, 2013, and all the benefits accruing therefrom under 35 U.S.C. §119, the disclosure of which is incorporated herein in its entirety by reference.

### BACKGROUND

1. Field

The invention relates to a vapor deposition apparatus.

2. Description of the Related Art

Each of semiconductor devices, display devices and other electronic devices includes a plurality of thin films. The plurality of thin films may be formed through various methods. Among these, a vapor deposition method may be one among the various methods.

The vapor deposition method uses a gas as a raw material for forming the thin films. Examples of the vapor deposition method include a chemical vapor deposition (“CVD”) method, an atomic layer deposition (“ALD”), method and other various methods.

Among these, in the ALD method, one raw material is injected into a vessel, and then purged and pumped, to adsorb a single molecular (e.g., atomic) layer or one layer among multiple layers on a substrate. Then, another raw material is injected into the vessel, and then purged and pumped, to finally form a desired single atomic layer or multiple atomic layers.

Organic light-emitting display devices have wider viewing angles, better contrast characteristics, and faster response speeds than other display devices, and thus have drawn attention as a next-generation display device. Such an organic light-emitting display apparatus includes an intermediate layer including an organic emission layer between first and second electrodes which are opposite to each other, and one or more various thin films. Here, a deposition process may be performed to form thin films of the organic light-emitting display devices.

### SUMMARY

One or more exemplary embodiments of the invention include a vapor deposition apparatus having improved deposition efficiency.

According to one or more exemplary embodiment of the invention, a vapor deposition apparatus includes: a substrate mount unit on which a substrate is mounted; a plurality of first nozzle units which injects a first raw material in a direction of the substrate mount unit; a plurality of second nozzle units which is alternately disposed with the plurality of first nozzle units and injects a second raw material in the direction of the substrate mount unit; and a plasma module unit which supplies the second raw material to the plurality of second nozzle units. The second raw material is a radical, and the substrate mount unit includes an electrostatic generation part.

The electrostatic generation part may include an electrode to which a direct current (“DC”) voltage may be applied.

Each first nozzle unit may selectively inject the first raw material and a purge gas in the direction of the substrate mount unit.

The vapor deposition apparatus may further include a switch unit which selectively supplies the first raw material and the purge gas, and each first nozzle unit may be connected to the switch unit.

The switch unit may include an inflow channel connected to the plurality of first nozzle units, a first raw material channel and a purge gas channel each connected to the inflow channel, and a first valve disposed in the first raw material channel, and a second valve disposed in the purge gas channel.

The vapor deposition apparatus may further include a sensor unit which senses a position of the substrate mount unit, and a control unit which receives position information corresponding to the position of the substrate mount unit.

The control unit may control an operation of the switch unit according to the position information.

Each first nozzle unit may inject the first raw material when the substrate mount unit is disposed under the plurality of first nozzle units.

The plasma module unit may include a plasma generator, a corresponding surface surrounding the plasma generator, and a plasma generating space defined between the plasma generator and the corresponding surface.

The vapor deposition apparatus may further include a diffusion unit between the plasma module unit and the plurality of second nozzle units.

The vapor deposition apparatus may further include an exhaust unit and a purge unit between a first nozzle unit among the plurality of first nozzle units, and a second nozzle unit among the plurality of second nozzle units and adjacent to the first nozzle unit in a moving direction of the substrate mount unit.

The vapor deposition apparatus may further include a first lower plate in which a plurality of slits is defined, and the first lower plate may be detachably coupled to a lower end of the first nozzle unit.

The vapor deposition apparatus may further include a plurality of second lower plates, and a plurality of slits defined in each second lower plate. The plurality of second lower plates may be respectively coupled to lower ends of the second nozzle unit and the purge unit.

According to one or more exemplary embodiments of the invention, a vapor deposition apparatus includes: a substrate mount unit on which a substrate is mounted, the substrate mount unit including an electrostatic generation part; a plurality of first nozzle units injecting a first raw material in a direction of the substrate mount unit; a plurality of second nozzle units which is alternately disposed with the plurality of first nozzle units and injects a second raw material having a radical form in the direction of the substrate mount unit; a diffusion unit which distributes the second raw material into the plurality of second nozzle units; and a plasma module unit which supplies the second raw material into the plurality of second nozzle units. The electrostatic generation part of the substrate mount unit induces the second raw material to the substrate mount unit.

The plasma module unit may include a plasma generator, a corresponding surface surrounding the plasma generator, and a plasma generating space defined between the plasma generator and the corresponding surface.

Each first nozzle unit may selectively inject the first raw material and a purge gas in the direction of the substrate mount unit.

Each first nozzle unit may inject the first raw material when the substrate mount unit is disposed under the plurality of first nozzle units.

The vapor deposition apparatus may further include a sensor unit which senses a position of the substrate mount unit, and a control unit which receives position information corresponding to the position of the substrate mount unit.

The vapor deposition apparatus may further include an exhaust unit and a purge unit between a first nozzle unit among the plurality of first nozzle units and a second nozzle unit among the plurality of second nozzle units and adjacent to the first nozzle unit in a moving direction of the substrate mount unit.

The vapor deposition apparatus may further include a plurality of lower plates, and a plurality of slits defined in each lower plate. The plurality of lower plates is detachably coupled to respective lower ends of the first nozzle unit, the second nozzle unit and the purge unit.

### BRIEF DESCRIPTION OF THE DRAWINGS

These and/or other features will become apparent and more readily appreciated from the following description of the exemplary embodiments, taken in conjunction with the accompanying drawings in which:

FIG. 1 is a schematic perspective view of an exemplary embodiment of a vapor deposition apparatus according to the invention;

FIG. 2 is a schematic cross-sectional view illustrating portion A of the vapor deposition apparatus of FIG. 1;

FIG. 3 is a schematic cross-sectional view illustrating an exemplary embodiment of a section of a first nozzle unit of the vapor deposition apparatus of FIG. 1.

FIG. 4 is a schematic plan view illustrating an exemplary embodiment of a lower plate of the vapor deposition apparatus of FIG. 1;

FIG. 5 is a schematic cross-sectional view of an exemplary embodiment of an organic light-emitting display device according to the invention; and

FIG. 6 is an enlarged view illustrating portion F of FIG. 5.

### DETAILED DESCRIPTION

Since the invention may have diverse modified embodiments, exemplary embodiments are illustrated in the drawings and are described in the detailed description of the invention. However, this does not limit the invention within specific embodiments and it should be understood that the invention covers all the modifications, equivalents, and replacements within the idea and technical scope of the invention. In describing the invention, when it is determined that the detailed description of the known art related to the invention may obscure the gist of the invention, the detailed description thereof will be omitted.

It will be understood that although the terms of first and second are used herein to describe various elements, these elements should not be limited by these terms. Terms are only used to distinguish one component from other components.

In the following description, the technical terms are used only for explaining a specific exemplary embodiment while not limiting the invention. The terms of a singular form may include plural forms unless referred to the contrary. In the drawings, the thickness or size of each layer is exaggerated, omitted, or schematically illustrated for convenience in description and clarity.

In addition, in describing each constituent element, when each constituent element is described to be formed “on” or “under” thereof, on and under all include those to be formed directly or through other constituent elements, and the criteria regarding on and under will be described based on the drawings. As used herein, connected may refer to elements being physically, electrically and/or fluidly connected to each other.

Hereinafter, exemplary embodiments of the invention are described in more detail with reference to the accompanying drawings and, while describing of the accompanying drawings, the same or corresponding components are given with the same number. Therefore, its overlapping description will be omitted.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

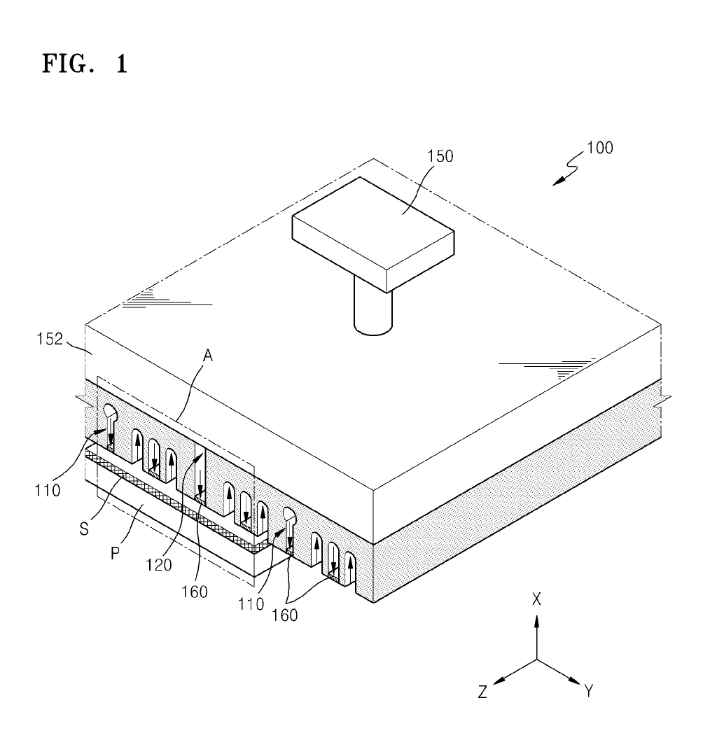

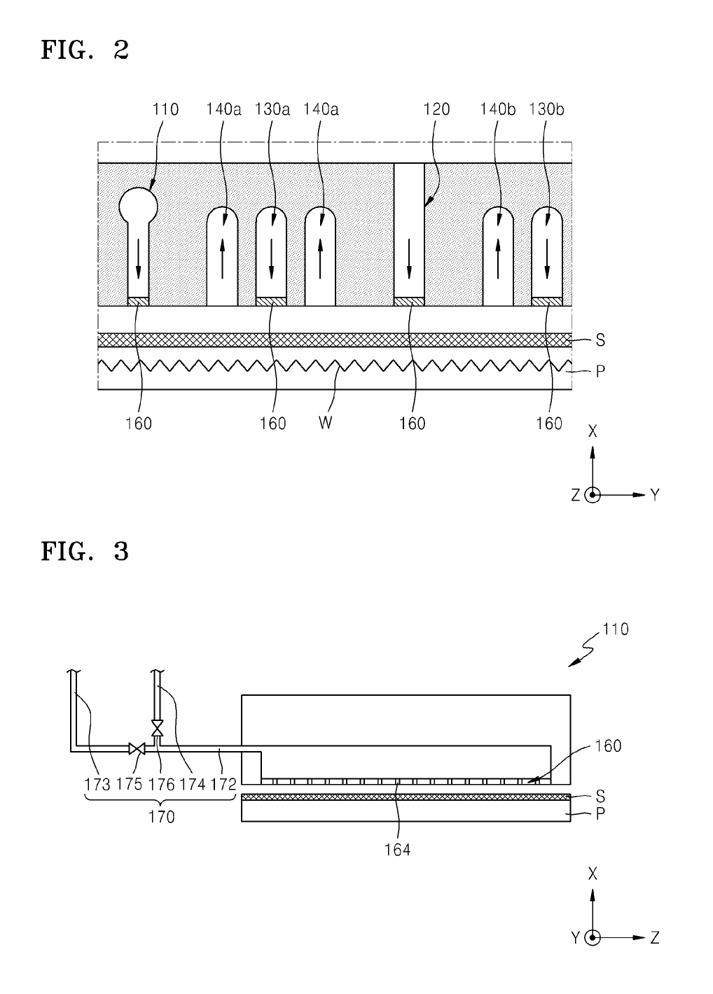

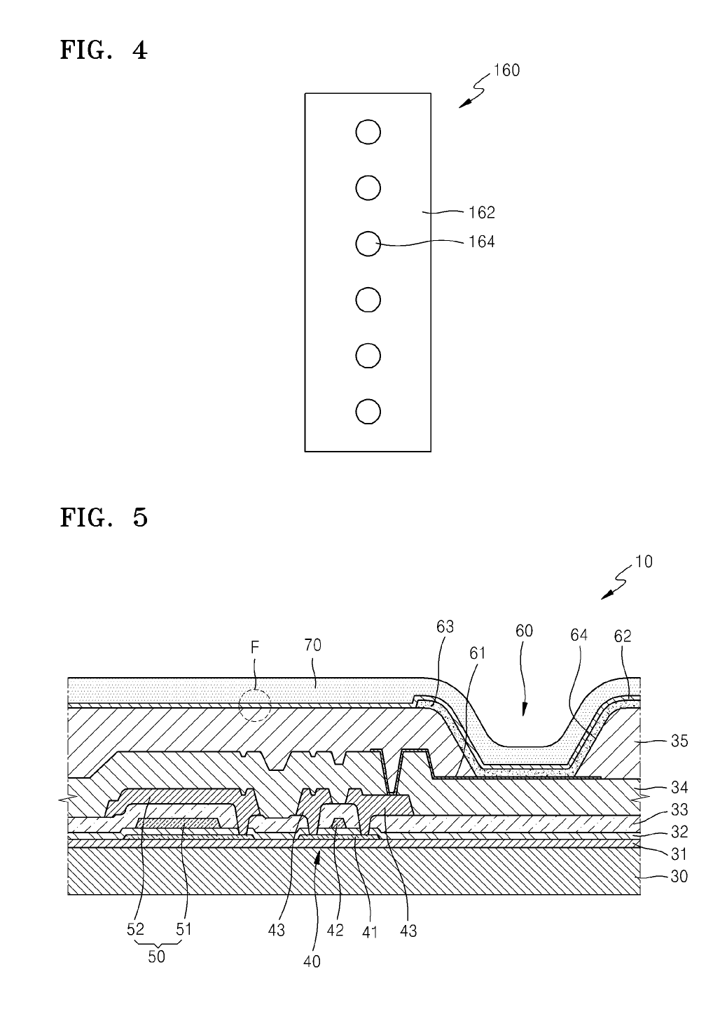

FIG. 1 is a schematic perspective view of an exemplary embodiment of a vapor deposition apparatus according to the invention, FIG. 2 is a schematic cross-sectional view illustrating portion A of the vapor deposition apparatus of FIG. 1, FIG. 3 is a schematic cross-sectional view illustrating a section of an exemplary embodiment of a first nozzle unit of the vapor deposition apparatus of FIG. 1, and FIG. 4 is a schematic plan view illustrating an exemplary embodiment of a lower plate of the vapor deposition apparatus of FIG. 1.

Referring to FIGS. 1 to 4, an exemplary embodiment of a vapor deposition apparatus 100 according to the invention may include a substrate mount unit P on which a substrate S is mounted, a plurality of first nozzle units 110 which injects a first raw material in a direction of the substrate mount unit P, a plurality of second nozzle units 120 which injects a second raw material in a direction of the substrate mount unit P, and a plasma module unit 150 supplying the second raw material to the plurality of second nozzle units 120.

Although not shown, the vapor deposition apparatus 100 may include a chamber (not shown) in which the substrate S and the substrate mount unit P are accommodated. The chamber may be connected to a pump (not shown) to control a pressure atmosphere within the chamber during a deposition process performed in the chamber. Also, the chamber may include at least one entrance (not shown) through which the substrate S is load or unloaded to and from the chamber, and a driving unit (not shown) for transferring or moving the substrate mount unit P.

The substrate mount unit P may mount the substrate S thereon and transfer the substrate S into the chamber (not shown). The substrate mount unit P may include a fixing unit (not shown) for fixing the substrate S with respect to the substrate mount unit P. The fixing unit (not shown) may be a clamp, a pressing unit, an adhesion material or other various kinds of units. The substrate mount unit P moves or reciprocates along one direction during the deposition process to adjust a thickness of a thin film deposited on the substrate S during the deposition process.

Also, the substrate mount unit P may include an electrostatic generation part. In one exemplary embodiment, for example, the electrostatic generation part may include an electrode W within the substrate mount unit P. When a direct current (“DC”) voltage is applied to the electrostatic generation part and/or the electrode W, the electrode W may generate static electricity. The static electricity generated in the substrate mount unit P may induce ions to the substrate mount unit P. In detail, as described below, as the second raw material having a radical form increases in directivity and mobility, dissipation of the second raw material may be minimized, and also, an amount of second raw material reaching the substrate S may increase to improve deposition efficiency of the vapor deposition apparatus 100.

The first nozzle units 110 may inject the first raw material in the direction of the substrate mount unit P. The first nozzle units 110 may be considered as defined in a body of the vapor deposition apparatus 100, or may be considered as including a flow path or flow channel for the first raw material and the portion of the body in which the flow path or flow channel defined. The first raw material may be supplied from a supply tank (not shown) to the first nozzle units 110. Here, the first raw material is supplied to the first nozzle units 110 in a horizontal direction. The horizontal direction may be defined in a plane of the body of the vapor deposition apparatus, such as in a Z-direction within a Y-Z plane with respect to FIG. 1. The horizontal direction may be parallel to a plane of the substrate mount unit P. That is, the first raw material supplied to the first nozzle units 110 in parallel with the substrate mount unit P, may be injected in the direction of the substrate mount unit P by the first nozzle units 110. An injection direction may be defined in a direction opposite to the X-direction with respect to FIG. 1. In one exemplary embodiment, the injection direction of the first raw material may be considered orthogonal to a supply direction of the first raw material.

The first nozzle units 110 may inject the first raw material in the direction of the substrate mount unit P as well as selectively inject a purge gas. In one exemplary embodiment, for example, if the substrate mount unit P is not disposed under the first nozzle units 110, the first nozzle units 110 may inject the purge gas instead of the first raw (e.g., source) material. That is, since the first nozzle units 110 intermittently supply the first raw material according to a position of the substrate mount unit P, a consumed amount of first raw material may decrease.

For this, the first nozzle units 110 are connected to a switch unit 170. The switch unit 170 includes an inflow pipe (e.g., inflow channel) 172 connected to the first nozzle units 110, a first raw material pipe 173 and purge gas pipe 174 connected to the inflow pipe 172, and a first valve 175 disposed in the first raw material pipe 173 and a second valve 176 disposed in the purge gas pipe 174 to selectively supply the first raw material or the purge gas into the first nozzle units 110, respectively.

In detail, if the substrate mount unit P is disposed under the first nozzle units 110, the first valve 175 may be opened and the second valve 176 may be closed, to supply the first raw material to the first nozzle units 110. With the second valve 176 closed while the first valve 175 is opened, the purge gas may not be supplied into the inflow pipe 172. Conversely, if the substrate mount unit P is not disposed under the first nozzle units 110, the first valve 175 may be closed and the second valve 176 may be opened to supply the purge gas to the first nozzle units 110. With the first valve 175 closed while the second valve 176 is opened, the first raw material may not be supplied into the inflow pipe 172.

Thus, since the raw material is selectively supplied, an overall consumed amount of first raw material may decrease, and injection of the first raw material into the chamber (not shown) when the substrate mount unit P is not disposed under the first nozzle units 110 may be reduced or effectively prevented to minimize contamination of the inside of the chamber (not shown) due to the first raw material. Also, in a conventional vapor deposition apparatus, a stabilizing plate is disposed on each of opposing sides of a related-art substrate mount unit to prevent unnecessary or unneeded first raw material from being injected into the chamber. Since the raw material is selectively supplied into the chamber with one or more exemplary embodiment of a vapor deposition apparatus according to the invention, the conventional stabilizing plate may be omitted to reduce an overall length or dimension of the vapor deposition apparatus 100.

The vapor deposition apparatus 100 may further include a sensor unit (not shown) sensing a position of the substrate mount unit P. The sensed position of the substrate mount unit P may be used to control an operation of the switch unit 170 according to a position of the substrate mount unit P. The vapor deposition apparatus 100 may further include a control unit (not shown) receiving position information of the substrate mount unit P from the sensor unit (not shown), and the received position information may be used to further control the operation of the switch unit 170.

A plurality of lower plates 160 is respectively detachably coupled to lower ends of the first nozzle units 110. The lower plate 160 may serve as a shower head type element to distribute and disperse material received thereby and passing therethrough. The lower plate 160 includes a plate-shaped body 162, and a plurality of slits 164 defined in the body 162 to uniformly inject the first raw material from the first nozzle units 110. The plurality of slits 164 may expose an inner area of the first nozzle units 110 in which the first raw material flows, to an outside of the first nozzle units 110 such that the first raw material may flow from the inner area to outside the first nozzle units 110. An individual lower plate 160 may be a single, unitary, indivisible member, and may solely define the slits 164.

Although the plurality of discrete slits 164 arranged in one line is illustrated in FIG. 4, the invention is not limited thereto. In an alternative exemplary embodiment, for example, the plurality of discrete slits 164 may be arranged in a plurality of rows extended in a length direction of the body 162 and arranged in a width direction perpendicular to the length direction of the body 162, or circularly and/or concentrically arranged. A shape of an individual slit 164 is not limited to the circular planar shape shown in FIG. 1, and exemplary embodiments of the slit 164 may include various planar shapes suitable for the purpose described herein. Since the lower plates 160 are respectively detachably coupled to the first nozzle units 110, replacing and cleaning processes thereof may be relatively easily performed. Also, lower plates 160 may be respectively detachably coupled to lower ends of the plurality of second nozzle units 120 and/or purge units 130a and 130b.

The second nozzle units 120 are alternately disposed with the plurality of first nozzle units 110 and inject the second raw material having the radical form in the direction of the substrate mount unit P. The second nozzle units 120 may be considered as defined in the body of the vapor deposition apparatus 100, or may be considered as including a flow path or flow channel for the second raw material and the portion of the body in which the flow path or flow channel defined. The second raw material having the radical form may be supplied into the second nozzle units 120 from the plasma module unit 150.

The plasma module unit 150 may be disposed inside or outside the chamber (not shown) and include a plasma generating unit (not shown) for generating plasma.

The plasma generating unit (not shown) may include a plasma generator to which a voltage is applied, a corresponding surface surrounding the plasma generator, and a plasma generating space defined between the plasma generator (not shown) and the corresponding surface. The plasma generator may be a cylindrical electrode to which a voltage is applied, and the corresponding surface may be a grounded electrode surrounding the plasma generator. However, the invention is not limited thereto. In one exemplary embodiment, for example, the plasma generator may be grounded, and a voltage may be applied to the corresponding surface.

In the plasma generating unit (not shown), when a pulse voltage is applied to the plasma generator to generate a potential difference between the plasma generator and the corresponding surface, plasma may be generated in the plasma generating space. Then, when the second raw material is injected into the plasma generating space (not shown) in which the plasma is generated, the second raw material may have the radical form. Also, since the plasma is generated within the plasma module unit 150 spaced apart from a region in which the deposition process is performed, damage of the substrate S due to the plasma may be reduced or effectively prevented.

The vapor deposition apparatus 100 may further include a diffusion unit 152 disposed between the plasma module unit 150 and the second nozzle units 120. The diffusion unit 152 may diffuse the second raw material supplied from the plasma module unit 150 to distribute the second raw material into the plurality of second nozzle units 120. Since the plasma module unit 150 may commonly supply the second raw material to the plurality of second nozzle units 120, the diffusion unit 152 distributes the second raw material into the plurality of second nozzle units 120.

In one exemplary embodiment, for example, the diffusion unit 152 may include a pipe or channel (not shown) connected to the plurality of second nozzle units 120. Alternatively, the diffusion unit 152 may include a plurality of plates (not shown). The plurality of plates (not shown) may be provided as several layers in a cross-sectional or thickness direction (e.g., X-direction) of the vapor deposition apparatus 100. A plurality of holes through which the second raw material passes may be defined in each of the plates (not shown) to adjust a moving path of the second raw material through the diffusion unit 152, thereby uniformly supplying the second raw material from the plasma module unit 150 to the plurality of nozzle units 120.

The second raw material injected through the plurality of second nozzle units 120 may be induced in the direction of the substrate mount unit P by the static electricity generated in the substrate mount unit P. That is, since the second raw material having the radical form increases in directivity and mobility, the second raw material having the radical form that may be easily dissipated may more easily reach the substrate S. Thus, uncontrolled or stray dissipation of the second raw material may be minimized, and an amount of second raw material reaching the substrate S may increase to improve the deposition efficiency of the vapor deposition apparatus 100.

The purge units 130a and 130b and exhaust units 140a and 140b may be further provided between the first and second nozzle units 110 and 120. The purge units 130a and 130b and exhaust units 140a and 140b may be considered as defined in the body of the vapor deposition apparatus 100, or may be considered as including a flow path or flow channel and the portion of the body in which the flow path or flow channel defined.

If it is assumed that the substrate mount unit P moves in a Y-direction, the purge units 130a and 130b may include a first purge unit 130a disposed at a position following the first nozzle unit 110 and a second purge unit disposed at a position following the second nozzle unit 120. Likewise, the exhaust units 140a and 140b may include a first exhaust unit 140a disposed at a position following the first nozzle unit 110 and a second exhaust unit 140b disposed at a position following the second nozzle unit 120 with respect to the same Y-moving direction of the substrate mount unit P.

The first purge unit 130a and the second purge unit 130b inject the purge gas in a direction of the substrate S. The purge gas may be a gas which does not affect the deposition process and does not actively contribute to a material being deposited on the substrate S, e.g., an argon gas or a nitrogen gas. The purge gas may pass from an inner area of the purge units 130a and 130b to an outside of the purge units 130a and 130b, via the slits 164 defined in the body 162 of the lower plate 160, but the invention is not limited thereto.

The first and second exhaust units 140a and 140b exhaust in a direction opposite to that of (e.g., away from) the substrate S, byproducts separated from the substrate S by the purge gas, and extra or unconsumed first and second raw materials which do not react during the deposition process.

Hereinafter, an exemplary embodiment of a method for forming a thin film on the substrate S by using the vapor deposition apparatus 100 will be described with reference to FIGS. 1 to 3. Also, an exemplary embodiment of a structure in which an AlₓO_{y} thin film is formed on the substrate S while the substrate mount unit P moves in the Y-direction of FIG. 1 will be described as an example. However, the invention is not limited thereto. In one exemplary embodiment, for example, the substrate mount unit P may reciprocate in the Y-direction indicated in the figures, and in a direction opposite to the Y-direction.

A method for forming a thin film on the substrate S by using the vapor deposition apparatus 100 includes mounting a substrate S that is an object on which a raw material is deposited, on the substrate mount unit P. When the substrate mount unit P, such as having the substrate mounted thereon, is disposed under one or more of the first nozzle units 110, a position of the substrate mount unit P is sensed by a sensor unit (not shown). The first nozzle unit 110 injects the first raw material in a direction of the substrate S under the control of a control unit (not shown) which receives position information sensed by the sensor unit.

In one exemplary embodiment, for example, the first raw material may be a gas including aluminum (Al) atoms such as trimethyl aluminium (“TMA”) that is in a gas state. Thus, a layer including adsorbed Al may be formed on a top surface of the substrate S. The formed adsorption layer may include a chemical adsorption layer and a physical adsorption layer. Here, the physical adsorption layer having relatively weak intermolecular coupling force may be separated from the substrate S by the purge gas injected from the first purge unit 130a that is disposed at a position following the first nozzle unit 110 with respect to a traveling direction of the substrate S. Also, the physical adsorption layer which has been separated from the substrate S may be effectively removed from the substrate S through pumping of the first exhaust unit 140a disposed at a position following the first nozzle unit 110 with respect to the traveling direction of the substrate S.

In succession, the substrate mount unit P may continuously move along the Y-direction, and the second nozzle unit 120 may inject the second raw material onto the substrate S. The second raw material has a radical shape. The second raw material may react with the chemical adsorption layer formed by the first raw material that is previously adsorbed on the substrate S or may be substituted for a portion of the chemical adsorption layer, to finally form a desired deposition layer including adsorbed material, for example, an AlₓO_{y} layer. However, the superfluous or remaining second raw material may remain on the substrate S as a physical adsorption layer.

The physical adsorption layer formed by the second raw material remaining on the substrate S may be separated from the substrate S by the purge gas injected from the second purge unit 130b disposed at a position following the second nozzle unit 120 with respect to the traveling direction of the substrate S, and then be effectively removed from the substrate S through pumping of the second exhaust unit 140b disposed at a position following the second nozzle unit 120 with respect to the traveling direction of the substrate S. Thus, a desired single molecular or atomic layer (e.g., thin film layer) may be formed on the substrate S.

As discussed above, the substrate mount unit P may include an electrostatic generation part for inducing the second raw material toward the substrate mount unit P. Thus, the second raw material may increase in directivity and mobility, and an amount of second raw material that participates in the above-described chemical reaction may increase to improve the deposition efficiency of the vapor deposition apparatus 100.

Also, as the substrate mount unit P continuously moves in the Y-direction, the substrate mount unit P may be positioned to not overlap the first nozzle unit 110. Here, the sensor unit (not shown) may sense a position of the substrate mount unit P, and then the control unit (not shown) receiving the position information may control the switch unit 170 to inject the purge gas from the first purge unit 130a instead of the first raw material from the first nozzle unit 110. Thus, the consumption of the first raw material may be reduced to minimize contamination of the inside of the chamber (not shown) due to the first raw material.

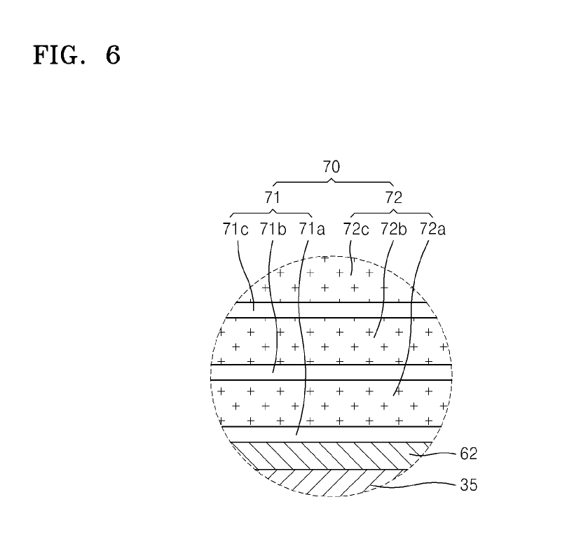

FIG. 5 is a schematic cross-sectional view of an exemplary embodiment of an organic light-emitting display device which may be manufactured by using the vapor deposition apparatus of FIG. 1, and FIG. 6 is an enlarged view illustrating portion F of FIG. 5.

In detail, FIGS. 5 and 6 illustrate an organic light-emitting display apparatus which may be manufactured by using the above-described vapor deposition apparatus (see reference numeral 100 of FIG. 1).

An organic light-emitting display apparatus 10 is disposed on a substrate 30. The substrate 30 may include a glass, plastic or metal material.

A buffer layer 31 provides a planarized surface on the substrate 30. The buffer layer 31 may include an insulation material for reducing or effectively preventing moisture and foreign substances from permeating in a direction of the substrate 30.

A thin film transistor (“TFT”) 40, a capacitor 50 and an organic light-emitting device 60 are disposed on the buffer layer 31. The TFT 40 includes an active layer 41, a gate electrode 42, and source and drain electrodes 43. The organic light-emitting device 60 includes a first electrode 61, a second electrode 62, and an intermediate layer 63.

The capacitor 50 includes a first capacitor electrode 51 and a second capacitor electrode 52.

In detail, the active layer 41 has a predetermined pattern and is disposed on a top surface of the buffer layer 31. The active layer 41 may include an inorganic semiconductor material such as silicon, an organic semiconductor material, or an oxide semiconductor material. In an exemplary embodiment of manufacturing an organic light-emitting display apparatus, the active layer 41 may be formed by doping a P-type or N-type dopant. The first capacitor electrode 51 may be disposed in the same layer as the gate electrode 42 and include a same material as the gate electrode 42.

A gate insulation layer 32 is disposed on the active layer 41. The gate electrode 42 is disposed on the gate insulation layer 32 to correspond to the active layer 41. An interlayer dielectric 33 is disposed to cover the gate electrode 42. The source and drain electrodes 43 are disposed on the interlayer dielectric 33 to contact a predetermined region of the active layer 41 via a contact hole defined in various layers of the organic light-emitting display apparatus. The second capacitor electrode 52 may be in a same layer (e.g., a same single layer) as the source and drain electrodes 43, and may include a same material as the source and drain electrodes 43.

A passivation layer 34 is disposed to cover the source and drain electrodes 43. A separate insulation layer (not shown) may be further disposed on the passivation layer 34 to planarize the thin film transistor 40.

The first electrode 61 is disposed on the passivation layer 34. The first electrode 61 is electrically connected to one of the source and drain electrodes 43 via a contact hole defined in the passivation layer 34. Also, a pixel defining layer 35 is disposed to cover the first electrode 61. A predetermined opening 64 is defined in the pixel defining layer 35. The intermediate layer 63 including the organic light-emitting layer is disposed within a region limited by the opening 64. The second electrode 62 is disposed on the intermediate layer 63 within the opening 64.

An encapsulation layer 70 is disposed on the second electrode 62. The encapsulation layer 70 may include an organic or inorganic material. Alternatively, the encapsulation layer 70 may have a structure in which the organic and inorganic materials are alternately stacked on each other.

In an exemplary embodiment of manufacturing an organic light-emitting display apparatus, the encapsulation layer 70 may be formed by using the above-described vapor deposition apparatus (see reference numeral 100 of FIG. 1). That is, the substrate 30 including the second electrode 62 disposed thereon may pass through the above-described vapor deposition apparatus (see reference numeral 100 of FIG. 1) to form a desired layer, such as a thin film layer.

Particularly, the encapsulation layer 70 may include an inorganic layer member 71 and an organic layer member 72. Also, the inorganic layer member 71 may include a plurality of layers 71a, 71b and 71c, and the organic layer member 72 may include a plurality of layers 72a, 72b and 72c. Here, the plurality of layers 71a, 71b and 71c of the inorganic layer member 71 may be respectively formed by using the vapor deposition apparatus (see reference numeral 100 of FIG. 1).

However, exemplary embodiments of the invention are not limited thereto. That is, other layers such as the buffer layer 31, the gate insulation layer 32, the interlayer dielectric 33, the passivation layer 34 and/or the pixel defining layer 35 of the organic light-emitting display device 10 may be formed by using the vapor deposition apparatus (see reference numeral 100 of FIG. 1).

Also, other various thin films such as the active layer 41, the gate electrode 42, the source and drain electrodes 43, the first electrode 61, the intermediate layer 63 and/or the second electrode 62 may also be formed by using the vapor deposition apparatus (see reference numeral 100 of FIG. 1).

As described above, when the vapor deposition apparatus (see reference numeral 100 of FIG. 1) is utilized, properties of the deposition films formed in the organic light-emitting display device 10 may be improved to improve electrical and image quality properties of the organic light-emitting display device 10.

One or more exemplary embodiment of the vapor deposition apparatus according to the invention may have an improved deposition efficiency.

Accordingly, a person having ordinary skill in the art will understand from the above that various modifications and other equivalent embodiments are also possible.

What is claimed is:

1. A vapor deposition apparatus comprising:
a substrate mount unit on which a substrate is mounted;
a plurality of first nozzle units which injects a first raw material in a direction of the substrate mount unit;
a plurality of second nozzle units which is alternately disposed with the plurality of first nozzle units, injects a second raw material in the direction of the substrate mount unit; and
a plasma module unit which supplies the second raw material to the plurality of second nozzle units,
wherein
the second raw material is a radical, and
the substrate mount unit comprises an electrostatic generation part.

2. The vapor deposition apparatus of claim 1, wherein the electrostatic generation part comprises an electrode to which a direct current voltage is applied.

3. The vapor deposition apparatus of claim 1, wherein each first nozzle unit among the plurality of first nozzle units selectively injects the first raw material and a purge gas, in the direction of the substrate mount unit.

4. The vapor deposition apparatus of claim 3, further comprising a switch unit which selectively supplies the first raw material and the purge gas,
wherein the each first nozzle unit is connected to the switch unit.

5. The vapor deposition apparatus of claim 4, wherein the switch unit comprises:
an inflow channel connected to the plurality of first nozzle units,
a first raw material channel and a purge gas channel each connected to the inflow channel, and
a first valve disposed in the first raw material channel, and a second valve disposed in the purge gas channel.

6. The vapor deposition apparatus of claim 4, further comprising:
a sensor unit which senses a position of the substrate mount unit, and
a control unit which receives position information corresponding to the position of the substrate mount unit.

7. The vapor deposition apparatus of claim 6, wherein the control unit controls an operation of the switch unit according to the position information.

8. The vapor deposition apparatus of claim 7, wherein the each first nozzle unit injects the first raw material when the substrate mount unit is disposed under the plurality of first nozzle units.

9. The vapor deposition apparatus of claim 1, wherein the plasma module unit comprises:
a plasma generator,
a corresponding surface surrounding the plasma generator, and
a plasma generating space defined between the plasma generator and the corresponding surface.

10. The vapor deposition apparatus of claim 9, further comprising a diffusion unit between the plasma module unit and the plurality of second nozzle units.

11. The vapor deposition apparatus of claim 1, further comprising an exhaust unit and a purge unit between a first nozzle unit among the plurality of first nozzle units, and a second nozzle unit among the plurality of second nozzle units and adjacent to the first nozzle unit in a moving direction of the substrate mount unit.

12. The vapor deposition apparatus of claim 11, further comprising a first lower plate in which a plurality of slits is defined,
wherein the first lower plate is detachably coupled to a lower end of the first nozzle unit.

13. The vapor deposition apparatus of claim 12, further comprising a plurality of second lower plates, and a plurality of slits defined in each second lower plate,
wherein the plurality of second lower plates is respectively coupled to lower ends of the second nozzle unit and the purge unit.

14. A vapor deposition apparatus comprising:
a substrate mount unit on which a substrate is mounted, the substrate mount unit comprising an electrostatic generation part;
a plurality of first nozzle units which injects a first raw material in a direction of the substrate mount unit;
a plurality of second nozzle units which is alternately disposed with the plurality of first nozzle units and injects a second raw material having a radical form, in the direction of the substrate mount unit;
a diffusion unit which distributes the second raw material into the plurality of second nozzle units; and
a plasma module unit which supplies the second raw material to the diffusion unit,
wherein the electrostatic generation part of the substrate mount unit induces the second raw material to the substrate mount unit.

15. The vapor deposition apparatus of claim 14, wherein the plasma module unit comprises:
a plasma generator,
a corresponding surface surrounding the plasma generator, and
a plasma generating space defined between the plasma generator and the corresponding surface.

16. The vapor deposition apparatus of claim 14, wherein each first nozzle unit among the plurality of first nozzle units selectively injects the first raw material and a purge gas in the direction of the substrate mount unit.

17. The vapor deposition apparatus of claim 16, wherein
the each first nozzle unit injects the first raw material when the substrate mount unit is disposed under the plurality of first nozzle units.

18. The vapor deposition apparatus of claim 17, further comprising:
a sensor unit which senses a position of the substrate mount unit, and
a control unit which receives position information corresponding to the position of the substrate mount unit.

19. The vapor deposition apparatus of claim 14, further comprising an exhaust unit and a purge unit between a first nozzle unit among the plurality of first nozzle units and a second nozzle unit among the plurality of second nozzle units and adjacent to the first nozzle unit in a moving direction of the substrate mount unit.

20. The vapor deposition apparatus of claim 19, further comprising a plurality of lower plates, and a plurality of slits defined in each lower plate,
wherein the plurality of lower plates is detachably coupled to respective lower ends of the first nozzle unit, the second nozzle unit and the purge unit.
